(19) United States
(12) Patent Application Publication
(10) Pub. No.: US 2018/0323064 A1
(43) Pub. Date: Nov. 8, 2018

(54) METHOD FOR CLEANING CHAMBER, METHOD FOR TREATING SUBSTRATE, AND APPARATUS FOR TREATING SUBSTRATE

(71) Applicant: SEMES CO., LTD., Cheonan-si (KR)

(72) Inventors: Jinwoo JUNG, Seoul (KR); Young Hun LEE, Asan-si (KR)

(73) Assignee: SEMES CO., LTD., Cheonan-si, (KR)

(21) Appl. No.: 15/965,000

(22) Filed: Apr. 27, 2018

(30) Foreign Application Priority Data
May 2, 2017 (KR) 10-2017-0056367

(51) Int. Cl. H01L 21/02; H01L 21/67; B08B 7/00; B08B 9/08

(52) U.S. Cl. CPC H01L 21/02101; H01L 21/67051; B08B 3/08; B08B 9/08; B08B 7/0021

(57) ABSTRACT

An apparatus and a method for cleaning a chamber are provided. A method for cleaning a chamber having a treatment space for treating a substrate includes cleaning the chamber by supplying a cleaning medium into the treatment space. The cleaning medium includes a supercritical fluid having a non-polar property and an organic solvent having a polar property. The cleaning efficiency of the chamber is improved with respect to a non-polar contaminant and a polar contaminant.

### CROSS-REFERENCE TO RELATED APPLICATIONS

This application claims priority under 35 U.S.C. § 119 to Korean Patent Application No. 10-2017-0056367 filed on May 2, 2017, in the Korean Intellectual Property Office, the disclosures of which are incorporated by reference herein in their entireties.

### BACKGROUND

Embodiments of the inventive concept relate to an apparatus and a method for cleaning a chamber.

In order to manufacture a semiconductor device, a desired pattern is formed on a substrate through various processes such as, photolithography, etching, ashing, ion implantation, and thin film deposition. Various treatment liquids are used in the processes, and contaminants and particles are produced during the process. In order to solve this, a cleaning process for cleaning contaminants and particles is essentially performed before and after each process.

In general, after the cleaning process is performed by chemicals or a rinse liquid, a drying process is performed. The drying process is to dry the rinse liquid remaining on the substrate, and the substrate is dried by using an organic solvent such as isopropyl alcohol (IPA). However, the critical dimension (CD) between patterns formed on the substrate is reduced to a fine size, the organic solvent remains in the space between the patterns and a supercritical treatment process is performed to remove the remaining organic solvent.

The supercritical treatment process is performed under the high-temperature and high-pressure atmosphere which is blocked from the outside. Accordingly, a supercritical treatment device has a complex structure. If contaminants are present inside the complex structure of the device, the fatal failure may be caused to the substrate. Therefore, to remove the contaminants, the cleaning process has to be periodically performed.

The supercritical treatment device performs the cleaning process for aging or rinsing of the device after being set up, or for removing contaminant remaining in the device after performing the supercritical treatment process.

FIG. 1 is a sectional view illustrating particles remaining in the inner space of the set-up supercritical treatment device. Referring to FIG. 1, since the supercritical treatment device has a sealed interior, the cleaning process is performed only by using a supercritical fluid. However, since the supercritical fluid typically has a non-polar property, it is difficult for the supercritical fluid to remove a contaminant A having a polar property.

As a prior art, there has disclosed Korean Unexamined Patent Publication No. 2012-0113181.

### SUMMARY

Embodiments of the inventive concept provide methods and apparatus capable of improving a rinsing efficiency of a supercritical treatment device.

Embodiments of the inventive concept provide methods and apparatuses capable of rapidly performing the cleaning process of a supercritical treatment device.

Embodiments of the inventive concept provide methods and apparatuses capable of easily rinsing each of non-polar contaminants and polar contaminants when rinsing the supercritical treatment device.

According to an exemplary embodiment, there are provided an apparatus and a method for cleaning a chamber.

A method for cleaning a chamber having a treatment space for treating a substrate includes cleaning the chamber by supplying a cleaning medium into the treatment space, in which the cleaning medium includes a supercritical fluid having a non-polar property and an organic solvent having a polar property.

The organic solvent may be supplied onto a dummy substrate from an outside of the chamber, and the dummy substrate having the organic solvent supplied at a specific thickness may be provided in the treatment space. The supercritical fluid may be supplied to the treatment space through a fluid supply line connected with the chamber, in a state that the dummy substrate may be provided in the treatment space and the treatment space is sealed from the outside.

The organic solvent may be supplied into the treatment space from a solvent nozzle provided at an outside of the chamber, in a state that the treatment space is open to the outside. The treatment space may be sealed from the outside after the organic solvent is supplied into the treatment space and then the supercritical fluid may be supplied into the treatment space through a fluid supply line connected with the chamber.

The organic solvent may be supplied into the treatment state through a solvent supply line connected with the chamber in a state that the treatment space is sealed from an outside. The supercritical fluid may be supplied into the treatment space through a fluid supply line connected with the chamber, in the state that the treatment space is sealed from the outside, the solvent supply line may be connected with the fluid supply line, and the organic solvent may be supplied to the treatment space through the fluid supply line. The organic solvent and the supercritical fluid may be simultaneously supplied.

The chamber may be a high-pressure chamber to perform a supercritical treatment process with respect to the substrate. The supercritical fluid may include a carbon dioxide (CO₂). The organic solvent may include one of methanol, ethanol, 1-propanol, acetone, acetonitrile, chloroform, dichloromethane, and ethyl acetate.

According to an exemplary embodiment, a method for treating a substrate includes cleaning an inner part of a chamber having a treatment space therein, and treating the substrate by supplying a supercritical fluid into the treatment space. The cleaning of the inner part of the chamber includes cleaning the chamber by supplying a cleaning medium to the treatment space, and the cleaning medium includes a supercritical fluid having a non-polar property and an organic solvent having a polar property.

The treating of the substrate may include drying the substrate.

The cleaning of the inner part of the chamber further may include supplying the organic solvent onto a dummy substrate from an outside of the chamber, providing the dummy substrate having the organic solvent supplied at a specific thickness in the treatment space, and supplying the supercritical fluid into the treatment space through a fluid supply line connected with the chamber, in a state that space and the treatment space is sealed from the outside when the dummy substrate is provided in the treatment.

The organic solvent may be supplied into the treatment space from a solvent nozzle provided at an outside of the chamber, in a state that the treatment space is open to the outside, and the treatment space may be sealed from the outside after the organic solvent is supplied into the treatment space and then the supercritical fluid may be supplied into the treatment space through a fluid supply line connected with the chamber.

The organic solvent may be supplied into the treatment state through a solvent supply line connected with the chamber in a state that the treatment space is sealed from an outside. The supercritical fluid may be supplied into the treatment space through a fluid supply line connected with the chamber, in the state that the treatment space is sealed from the outside. The solvent supply line may be connected with the fluid supply line, and the organic solvent may be supplied into the treatment space through the fluid supply line.

The supercritical fluid may include CO₂, and the organic solvent may include one of methanol, ethanol, 1-propanol, acetone, acetonitrile, chloroform, di chloromethane, and ethyl acetate.

According to an exemplary embodiment, an apparatus for treating a substrate includes a chamber having a treatment space therein, a fluid supply line connected with the chamber and to supply a supercritical fluid having a non-polar property into the treatment space, and a solvent supply unit to supply an organic solvent, which has a polar property, into the treatment space.

The chamber may be a drying chamber to perform a process of drying the substrate. The apparatus further may include a liquid treatment chamber to perform a liquid treatment process with respect to the substrate. The solvent supply unit may include a dummy substrate, and a solvent supply line connected with the liquid treatment chamber and to supply the organic solvent to the dummy substrate. The organic solvent may be supplied onto the dummy substrate in the liquid treatment chamber, and the organic solvent may be supplied into the treatment space as the dummy substrate having the organic solvent is provided into the treatment space.

The solvent supply unit may include a solvent nozzle provided independently from the chamber outside the chamber and may directly supply the organic solvent into the treatment space in a state that the treatment space is open.

The solvent supply unit may include a solvent supply line connected with the fluid supply unit and may supply the organic solvent.

### BRIEF DESCRIPTION OF THE FIGURES

The above and other objects and features of the inventive concept will become apparent by describing in detail exemplary embodiments thereof with reference to the accompanying drawings.

FIG. 1 is a sectional view illustrating particles remaining in an inner space of a supercritical treatment apparatus which is set up;

FIG. 2 is a plan view illustrating a substrate treating facility, according to an embodiment of the inventive concept;

FIG. 3 is a sectional view illustrating an apparatus for cleaning a substrate in a first process chamber of FIG. 2;

FIG. 4 is a sectional view illustrating an apparatus for drying a substrate in a second process chamber of FIG. 2, according to an embodiment;

FIG. 5 is a perspective view illustrating a substrate support unit of FIG. 4;

FIG. 6 is a flowchart illustrating the step of treating the substrate in the second process chamber of FIG. 4;

FIGS. 7 and 8 are views illustrating a procedure of treating a substrate of FIG. 6;

FIG. 9 is a sectional view illustrating a second process chamber of FIG. 4, according to a second embodiment;

FIG. 10 is a flowchart illustrating the step of treating the substrate in the second process chamber of FIG. 9;

FIG. 11 is a sectional view illustrating the second process chamber of FIG. 4, according to a third embodiment; and

FIG. 12 is a flowchart illustrating the step of treating the substrate in the second process chamber of FIG. 11.

### DETAILED DESCRIPTION

The embodiments of the inventive concept may be modified in various forms, and the scope of the inventive concept should not be construed to be limited by the embodiments of the inventive concept described in the following. The embodiments of the inventive concept are provided to describe the inventive concept for those skilled in the art more completely. Accordingly, the shapes and the like of the components in the drawings are exaggerated to emphasize clearer descriptions.

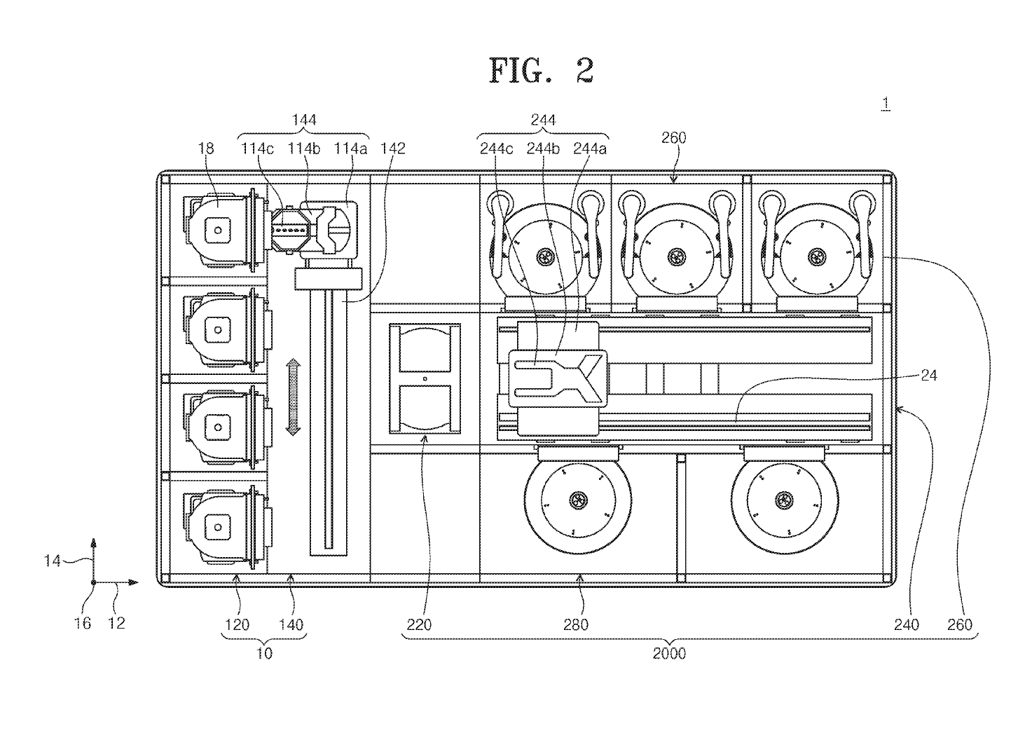

Hereinafter, an embodiment of the inventive concept will be described with reference to FIGS. 2 to 12.

FIG. 2 is a plan view illustrating a substrate treating facility, according to an embodiment of the inventive concept;

Referring to FIG. 2, a substrate treating facility 1 has an index module 10 and a process treating module 2000, and the index module 10 includes a load port 120 and a feeding frame 140. The load port 120, the feeding frame 140, and the process treating module 2000 may be sequentially arranged in a row. Hereinafter, a direction in which the load port 120, the feeding frame 140, and the process treating module 2000 are arranged will be referred to as a first direction 12, a direction that is perpendicular to the first direction 12 when viewed from the top will be referred to as a second direction 14, and a direction that is normal to a plane containing the first direction 12 and the second direction 14 will be referred to as a third direction 16.

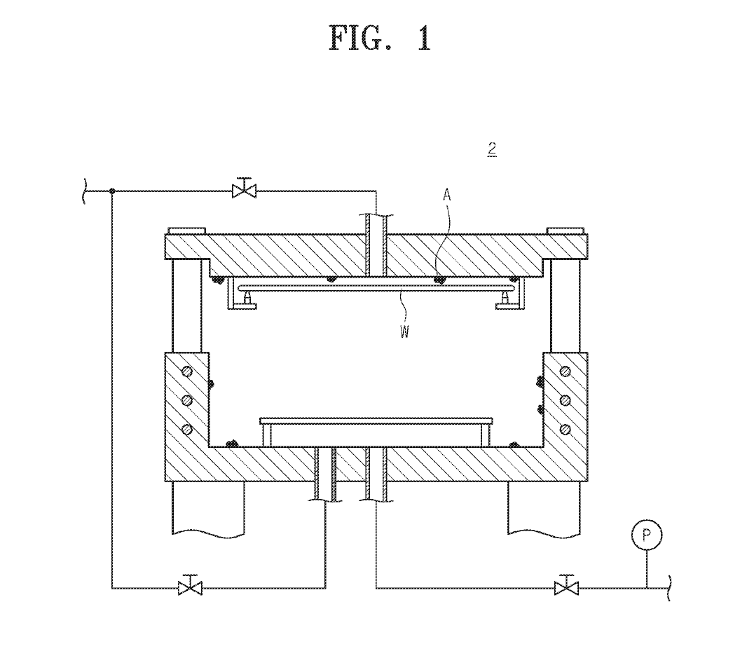

A carrier 18 having a substrate “W” received therein is seated on the load port 120. A plurality of load ports 120 are provided, and are arranged in the second direction 14 in a line. FIG. 1 illustrates that four load ports 120 are provided. However, the number of the load ports 120 may increase or decrease depending on a condition, such as the process efficiency of the process treating module 2000 or a footprint. A slot (not illustrated) is formed in the carrier 18 to support the edge of the substrate. A plurality of slots are provided in the third direction 16, and substrates are positioned in the carrier 18 such that the substrates are stacked in the third direction 16 while being spaced apart from each other. A front opening unified pod (FOUP) may be used as the carrier 18.

The process treating module 2000 includes a buffer unit 220, a feeding chamber 240, a first process chamber 260, and a second process chamber 280. The feeding chamber 240 is disposed such that the lengthwise direction thereof is in parallel to the first direction 12. First process chambers 260 are arranged at one side of the feeding chamber 240 in the second direction 14, and second process chambers 280 are arranged on an opposite side of the feeding chamber 240 in the second direction 14. The first process chambers 260 and the second process chambers 280 may be arranged to be symmetrical to each other about the feeding chamber 240. Some of the first process chambers 260 are arranged in the lengthwise direction of the feeding chamber 240. Furthermore, others of the first process chambers 260 are arranged to be stacked on each other. In other words, the first process chambers 260 may be arranged in the form of a matrix of A×B (A and B are natural numbers) at one side of the feeding chamber 240. Here, A is the number of the first process chambers 260 provided in a line in the first direction 12, and B is the number of the second process chambers 280 provided in a line in the third direction 16. When four or six first process chambers 260 are provided at one side of the feeding chamber 240, the first process chambers 260 may be arranged in 2×2 or 3×2. The number of the first process chambers 260 may increase or decrease. Similarly to the first process chambers 260, the second process chambers 280 may be arranged in the form of a matrix M×N (M and N are natural numbers). Here, M and N may be equal to A and B, respectively. Unlike the above description, the first process chambers 260 and the second process chambers 280 may be provided only on one side of the feeding chamber 240. Further, unlike the above description, the first process chambers 260 and the second process chambers 280 may be provided in a single layer at opposite sides of the feeding chamber 240. In addition, unlike the above description, the first process chambers 260 and the second process chambers 280 may be provided in various arrangements.

The buffer unit 220 is interposed between the feeding frame 140 and the feeding chamber 240. The buffer unit 220 provides a space between the feeding chamber 240 and the feeding frame 140 such that the substrate “W” stays in the space before being carried. The buffer unit 220 has a slot (not illustrated) that the substrate “W” is placed and a plurality of slots (not illustrated) are provided to be spaced apart from each other in the third direction 16. The buffer unit 220 is open in surfaces facing the feeding frame 140 and the feeding chamber 240.

The feeding frame 140 transports the substrate “W” between the carrier 18 seated on the load port 120 and the buffer unit 220. An index rail 142 and an index robot 144 are provided in the feeding frame 140. The index rail 142 is provided such that the lengthwise direction thereof is in parallel to the second direction 14. The index robot 144 is installed on the index rail 142 to linearly move in the second direction 14 along the index rail 142. The index robot 144 has a base 114a, a body 114b, and a plurality of index arms 114c. The base 114a is installed to be movable along the index rail 142. The body 114b is coupled to the base 114a. The body 114b is provided to be movable in the third direction 16 on the base 114a. The body 141b is provided to be rotatable on the base 114a. The index arms 114c are coupled to the body 114b, and are provided to move forward and rearward from the body 114b. A plurality of index arms 114c are provided to be driven individually. The index arms 114c are disposed to be stacked while being spaced apart from each other in the third direction 16. Some of the index arms 114c are used when carrying the substrates “W” to the carrier 18 from the process treating module 2000, and some of the index arms 114c may be used when carrying the substrates W from the carrier 18 to the process treating module 2000. This structure may prevent particles, which are produced from the substrates “W” before the process treatment, from sticking to the substrates “W” after the process treatment in the process of introducing the substrates “W” in and out of by the index robot 144.

The feeding chamber 240 transfers the substrate “W” between any two of the buffer unit 220, the first process chambers 260, and the second process chambers 280. A guide rail 242 and a main robot 244 are provided in the feeding chamber 240. The guide rail 242 is disposed such that the lengthwise direction thereof is parallel to the first direction 12. The main robot 244 is installed on the guide rail 242 to move in the first direction 12 on the guide rail 242.

The first process chamber 260 and the second process chamber 280 may sequentially perform a process on one substrate “W”. For example, the substrate “W” may be subject to a liquid treatment process, such as a chemical process, a cleaning process, and a substitution process, in the first process chamber 260, and a drying process in the second process chamber 280. The substation process may be performed by using an organic solvent and the drying process may be performed by using a supercritical fluid. An isopropyl alcohol (IPA) liquid may be used as the organic solvent, and carbon dioxide (CO₂) may be used as the supercritical fluid. Alternatively, the substitution process may be omitted from the first process chamber 260. For example, the first process chamber 260 may be provided for a liquid treatment process and the second process chamber 280 may be provided as a drying chamber.

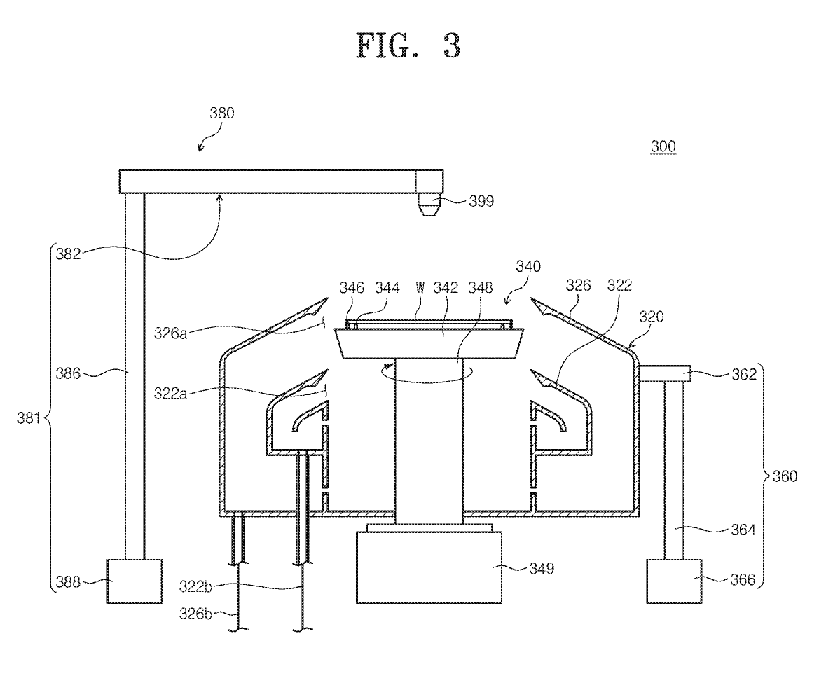

Hereinafter, the first process chamber 260 performing the liquid treatment process will be described. FIG. 3 is a sectional view illustrating an apparatus for cleaning the substrate in the first process chamber of FIG. 2. Referring to FIG. 3, the first process chamber 260 includes a treatment container 320, a spin head 340, an elevation unit 360, and a spray member 380. The treatment container 320 provides a space in which a substrate treating process is performed, and an upper portion of the treatment container 320 is opened. The treatment container 320 includes an inner recovery vessel 322 and an outer recovery vessel 326. The recovery vessels 322 and 326 recover mutually different treatment liquids used in the process. The inner recovery vessel 322 is provided to have an annular ring shape that surrounds the spin head 340, and the outer recovery vessel 326 is provided to have an annular ring shape that surrounds the inner recovery vessel 322. An inner space 322a of the inner recovery vessel 322 and a space 326a between the outer recovery vessel 326 and the inner recovery vessel 322 function as inlets for introducing the treatment liquids into the inner recovery vessel 322 and the outer recovery vessel 326, respectively. Recovery lines 322b and 326b are connected with the recovery vessels 322 and 326 while vertically extending downward from the bottom surface the recovery vessels 322 and 326. The recovery lines 322b and 326b are to discharge the treatment liquids introduced into the recovery vessels 322 and 326, respectively. The discharged treatment liquids may be recycled through an external treatment liquid recycling system (not illustrated).

The spin head 340 is arranged in the treatment container 320. The spin head 340 rotates the substrate “W” while supporting the substrate “W” during the process. The spin head 340 has a body 342, a support pin 344, a chuck pin 346, and a support shaft 348. The body 342 has a top surface provided in a substantially circular shape when viewed from the top. The support shaft 348 is fixed coupled to the bottom surface of the body 342 to be rotatable by a motor 349. A plurality of support pins 344 are provided. The support pins 344 may be arranged to be spaced apart from each other at an edge part of the top surface of the body 342 while protruding upward from the body 342. The support pins 344 are arranged to form a typical annular ring shape through combination thereof. The support pins 344 support an edge of a rear surface of the substrate “W” such that the substrate “W” is spaced apart from the top surface of the body 342 by a specific distance. A plurality of chuck pins 346 are provided. The chuck pins 346 are arranged to be farther apart from the center of the body 342 as compared with the support pins 344 are apart from the center of the body 342. The chuck pins 346 are provided to protrude upward from the body 342. The chuck pins 346 support a side portion of the substrate “W” such that the substrate “W” is not separated laterally from a right position thereof when the spin head 340 rotates. The chuck pins 346 are provided to be linearly movable between a standby position and a support position in a radial direction of the body 342. The standby position is farther apart from the center of the body 342 as compared with the support position is apart from the center of the body 342 When the substrate “W” is loaded on or unloaded from the spin head 340, the chuck pins 346 are positioned at the standby position. When a process is performed with respect to the substrate “W”, the chuck pins 346 are positioned at the support position. The chuck pins 346 are in contact with the side portion of the substrate “W” at the support position.

The elevation unit 360 linearly moves the treatment container 320 upward and downward. As the treatment container 320 moves upward and downward, a relative height of the treatment container 320 to the spin head 340 is changed. The elevation unit 360 has a bracket 362, a movable shaft 364, and a driver 366. The bracket 362 is fixedly installed on an outer wall of the treatment container 320, and the movable shaft 364 is fixedly coupled to the bracket 362 to move upward and downward by the driver 366 When the substrate “W” is placed on the spin head 340 or lifted from the spin head 340, the treatment container 320 moves downward such that the spin head 340 protrudes upward from the treatment container 320. The height of the treatment container 320 is adjusted such that the treatment liquid is introduced into the recovery vessel 360 preset depending on the type of the treatment liquid supplied to the substrate “W” when the process is performed.

Alternatively, the elevation unit 360 may move the spin head 340 upward and downward instead of the treatment container 320.

The spray member 380 supplies the treatment liquid onto the substrate “W”. The spray member 380 has a nozzle support 382, a nozzle 399, a support shaft 386, and a driver 388. The support shaft 386 has a lengthwise direction provided in the third direction and the driver 388 is coupled to the lower end of the support shaft 386. The driver 388 rotates and elevates the support shaft 386. The nozzle support 382 is coupled to an end of the support shaft 386, which is opposite to an end of the support shaft 386 coupled to the driver 388, perpendicularly to the support shaft 386. The nozzle 399 is installed on a bottom surface of an end of the nozzle support 382. The nozzle 399 is moved to a process position and a standby position by the driver 388. The process position is a position at which the nozzle 399 is arranged at the vertical upper portion of the treatment container 320, and the standby position is a position that is out of the vertical upper portion of the treatment container 320. One or a plurality of spray members 380 may be provided. When a plurality of spray members 380 are provided, the chemicals, the rinsing liquid, and the organic solvent may be provided through mutually different spray members 380. The chemicals may be a liquid having a strong acid or alkali property. The rinsing liquid may be pure. The organic solvent may be a mixture of vapor of isopropyl alcohol and an inert gas or an isopropyl alcohol liquid.

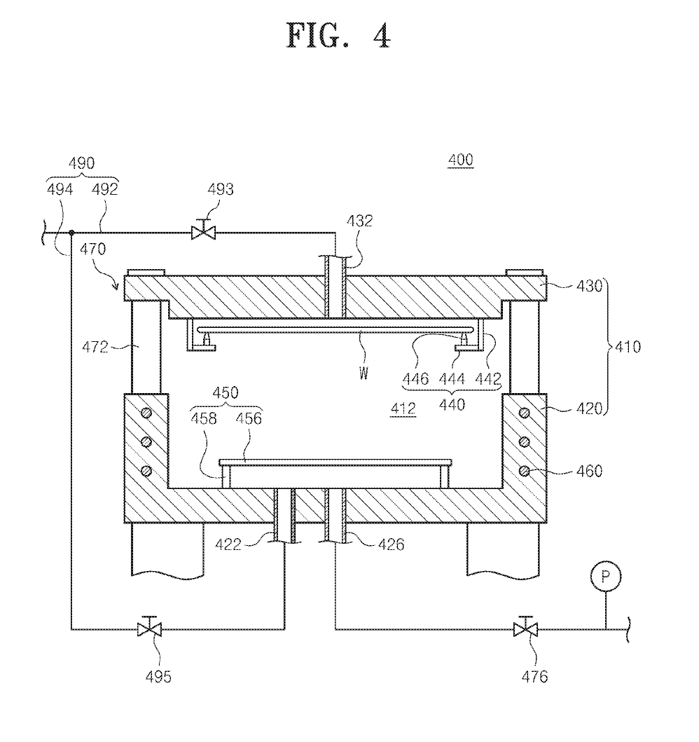

A device 400 that performs a secondary drying process of the substrate “W” is provided in the second process chamber 280. In the second process chamber 280, the substrate “W”, which is primarily dried in the first process chamber 260, is secondarily dried. In the second process chamber 280, the substrate “W” having remaining organic solvent is dried. In the second process chamber 280, the substrate “W” is dried by using by using a supercritical fluid. FIG. 4 is a sectional view illustrating an apparatus for drying a substrate in a second process chamber of FIG. 2, according to an embodiment. Referring to FIG. 4, the second process chamber 280 includes a high-pressure chamber 410, a body elevating member 470, a substrate support unit 440, a blocking member 450, a heating member 460, a fluid supply unit 490, a solvent supply unit 500, and a controller (not shown).

The high-pressure chamber 410 is formed therein with a treatment space 412 for processing the substrate “W”. When the treatment space 412 arrives at critical pressure and a critical temperature, the supercritical atmosphere may be formed. In the high-pressure chamber 410, the treatment space 412 may be sealed from the outside during the process of the substrate “W”. The high-pressure chamber 410 includes a lower body 420 an upper body 430. The lower body 420 has the shape of a cup having an open upper portion. A lower supply port 422 and a discharge port 426 are formed in a bottom surface of the lower body 420. The lower supply port 422 functions as a passage for supplying the supercritical fluid to the treatment space 412. When viewed from the top, the lower supply port 422 may be positioned eccentrically from the central axis of the lower body 420. The discharge port 426 discharges atmosphere gas of the treatment space 412. When viewed from the top, the discharge port 426 may be positioned eccentrically from the central axis of the lower body 420.

The upper body 430 is combined with the lower body 420 to define a treatment space 412 therebetween. The upper body 430 is positioned above the lower body 420. The upper body 430 is provided in the form of a plate. An upper supply port 432 is formed in the upper body 430. The upper supply port 432 functions as a passage for supplying the supercritical fluid to the treatment space 412. The upper supply port 432 may be positioned to coincide with the center of the upper body 430. The upper body 430 may be provided such that the lower end of the upper body 430 faces the upper end of the lower body 420 at a position that the central axis of the upper body 430 coincides with the central axis of the lower body 420. According to an embodiment, the upper body 430 and the lower body 420 may be formed of metallic materials.

The body elevating member 470 adjusts the relative height between the upper body 430 and the lower body 420. The body elevating member 470 moves one of the upper body 430 and the lower body 420 upward or downward. The present embodiment has been described in that that the distance between the upper body 430 and the lower body 420 is adjusted by fixing the position of the upper body 430 and by moving the lower body 420. The body elevating member 470 opens or closes the treatment space 412 by moving upward or downward the lower body 420. The body elevating member 470 moves the lower body 420 such that the relative position between the upper body 430 and the lower body 420 is a closed position or an open position. In this case, the closed position is defined as a position that the treatment space 412 is sealed from the outside, as the upper body 430 and the lower body 420 are in close contact with each other. The open position is defined as a position that the upper body 430 and the lower body 420 are spaced apart from each other such that the substrate “W” is introduced or withdrawn. The body elevating member 470 includes a plurality of elevating shafts 472 lining the upper body 430 to the lower body 420. The elevating shafts 472 are interposed between the lower body 420 and the upper body 430. The elevating shafts 472 are positioned to be arranged along the edge of the upper end of the lower body 420. The elevating shafts 472 may be fixedly coupled to the upper end of the lower body 420 while passing through the upper body 430. As the elevating shafts 472 move upward or downward, the height of the lower body 420 may be changed and the distance between the upper body 430 and the lower body 420 may be adjusted. For example, the elevating shafts 472 may move upward or downward by a cylinder.

Alternatively, a substrate support unit 440 may be installed on the fixed lower body 420 and the upper body 430 may move.

The substrate support unit 440 supports the substrate “W” in the treatment space 412. The substrate support unit 440 supports the substrate “W” such that the treatment surface of the substrate “W” faces up. The substrate support unit 440 supports the edge region of the substrate “W”.

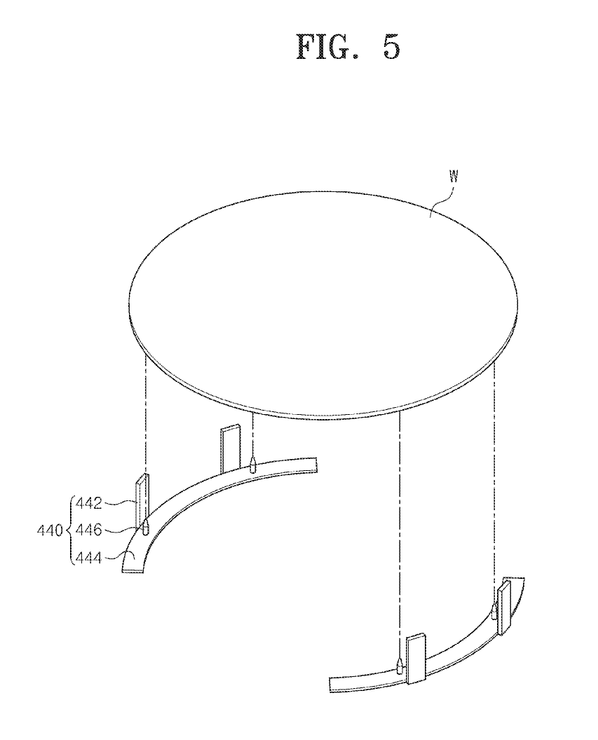

FIG. 5 is a perspective view illustrating the substrate support unit of FIG. 4. Referring to FIG. 5, the substrate support unit 440 includes an upper support 442, a substrate maintaining unit 444, and a support pin 446. The upper support 442 is provided in the form of a bar extending downward from the bottom surface of the upper body 430. A plurality of upper supports 442 are provided. For example, four upper supports 442 may be provided. The substrate maintaining unit 444 has an arc shape. The substrate maintaining unit 444 extends from the lower end of the upper support 442 perpendicularly to the upper support 442. The substrate maintaining unit 444 extends inward from the upper support 442. For example, two substrate maintaining units 444 may be provided. The substrate maintaining units 444 are assembled with each other to form a ring shape. The substrate maintaining units 444 are spaced apart from each other. The support pin 446 extends while protruding upward from the top surface of the substrate maintaining unit 444. The upper end of the support pin 446 is provided as a region for directly supporting the edge region of the bottom surface of the substrate “W”. For example, four support pins 446 may be provided.

Referring back to FIG. 4, a blocking member 450 includes a blocking plate 456 and a lower support 458. The blocking plate 456 is interposed between the lower supply port 422 and the substrate support unit 440 in the treatment space 412. The blocking plate 456 is provided to have a circular plate shape. The blocking plate 456 has a diameter smaller than an inner diameter of the lower body 420. When viewed from the top, the blocking plate 456 has a diameter to cover all the lower supply port 422 and the discharge port 426. Accordingly, the flow path of a treatment fluid supplied through the lower supply port 422 is bypassed by the blocking plate 456. In other words, the blocking plate 456 blocks the supercritical fluid, which is supplied through the lower supply port 422, from directly being supplied to a non-treatment surface of the substrate “W”. For example, the blocking plate 456 may be provided to have a diameter equal to or greater than a diameter of the substrate “W”. The lower support 458 supports the blocking plate 456. A plurality of lower supports 458 are provided and arranged along the circumference of the blocking plate 456. The lower supports 458 may be arranged to be spaced apart from each other by a uniform distance.

The heating member 460 heats the treatment space 412. The heating member 460 heats the supercritical fluid supplied to the treatment space 12 to a critical temperature or more such that the supercritical fluid is maintained in a supercritical fluid phase. The heating member 460 may be buried in at least one of the upper body 430 and the lower body 420 for the installation of the heating member 460. For example, the heating member 460 may be provided in the form of a heater to generate heat by receiving power from the outside.

A fluid supply unit 490 supplies a treatment fluid to the treatment space 412. The treatment fluid is supplied in a supercritical state by a supercritical temperature and a supercritical pressure. The fluid supply unit 490 includes fluid supply lines 492 and 494. The fluid supply lines 492 and 494 include an upper supply line 492 and a lower supply line 494. The upper supply line 492 is connected with the upper supply port 432. The treatment fluid is supplied to the treatment space 412 sequentially via the upper supply line 492 and the upper supply port 432. An upper valve 493 is installed on the upper supply line 492. The upper valve 493 opens and closes the upper supply line 492. The lower supply line 494 connects the upper supply line 492 with the lower supply port 422. The lower supply line 494 branches from the upper supply line 492 and is connected with the lower supply port 422. That is, the treatment fluids supplied through the upper supply line 492 and the lower supply line 494 may be the same type of fluids. The treatment fluid is supplied to the treatment space 412 sequentially via the lower supply line 494 and the lower supply port 422. A lower valve 495 is installed in the lower supply line 494. The lower valve 495 opens and closes the lower supply line 494. For example, the treatment fluid may be a non-polar fluid in the supercritical state by the supercritical temperature and supercritical pressure. The treatment fluid may include carbon dioxide (CO₂).

According to an embodiment, a treatment fluid may be supplied through the lower supply port 422 facing a non-treatment surface of the substrate “W”, and then may be supplied from the upper supply port 432 facing a treatment surface of the substrate “W”. Accordingly, the treatment fluid may be supplied to the treatment space 412 through the lower supply line 494, and then may be supplied to the treatment space 412 through the upper supply line 492. This is because the treatment fluid supplied at the initial stage may be prevented from being supplied to the substrate “W” without reaching the critical pressure or the critical temperature.

A solvent supply unit 500 supplies an organic solvent to the treatment space 412. The organic solvent is used for the cleaning process of the high-pressure chamber 410 instead of the drying process for the substrate “W”. The organic solvent is introduced into the treatment space 412 from the outside of the high-pressure chamber 410. The solvent supply unit 500 includes a dummy substrate 510 and a solvent supply line 520. Before describing the dummy substrate 510, the substrate “W” is defined as a process substrate “W” subject to the treatment process for fabricating a semiconductor device. Conversely, the dummy substrate 510 is not subject to the treatment process although the dummy substrate 510 has the same shape as the shape of the process substrate “W”. The dummy substrate 510 is temporarily stored in the buffer unit 220. The dummy substrate 510 is carried to the buffer unit 220, the first process chamber 260, and the second process chamber 280 by the main robot 244.

Alternatively, although the dummy substrate 510 has the shape different from the shape of the process substrate “W”, the shape of the dummy substrate 510 may be changed as long as the dummy substrate 510 has the size allowing the seating on the buffer unit 220, the main robot 244, the spin head 340, and the substrate support unit 440.

The solvent supply line 520 is linked to the spray member 380 of the first process chamber 260. The spray member 380 discharges an organic solvent supplied from the solvent supply line 520. The spray member supplying the organic solvent is provided to be different from the spray member 380 to discharge a liquid different from the organic solvent. Chemicals, a rinsing liquid, an organic solution, and an organic solvent are discharged through spray members 380 mutually different from each other.

For example, the organic solvent has a polar property. The organic solvent may include one of methanol, ethanol, 1-propanol, acetone, acetonitrile, chloroform, dichloromethane, and ethyl acetate, or more.

The controller (not illustrated) controls the main robot 244, the first process chamber 260, and the second process chamber 280 such that the inner part of the high-pressure chamber 410 is cleaned by supplying a rinsing medium to the treatment space 412. In this case, the rinsing medium includes the above-described supercritical fluid and the organic solvent. The controller (not illustrated) controls the main robot 244, the first process chamber 260, and the second process chamber 280 such that the organic solvent supplied from the first process chamber 260 is supplied to the treatment space 412 in the second process chamber.

According to an embodiment, the controller (not illustrated) may clean the high-pressure chamber 410 by carrying the dummy substrate 510, which is temporarily stored in the buffer unit 220, to the first process chamber 260, supplying the organic solvent onto the dummy substrate 510 in the first process chamber 260, and carrying the dummy substrate 510 having the remaining the organic solvent into the second process chamber 280.

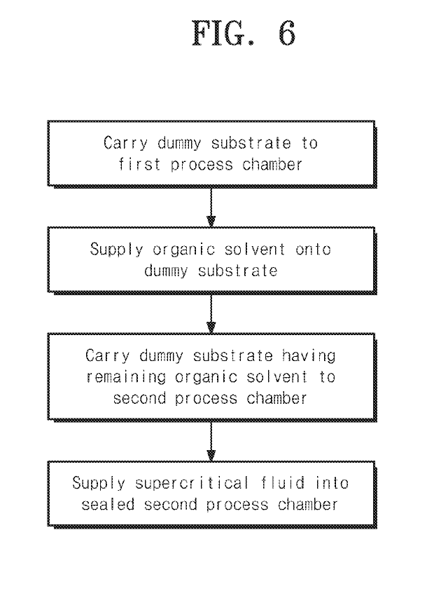

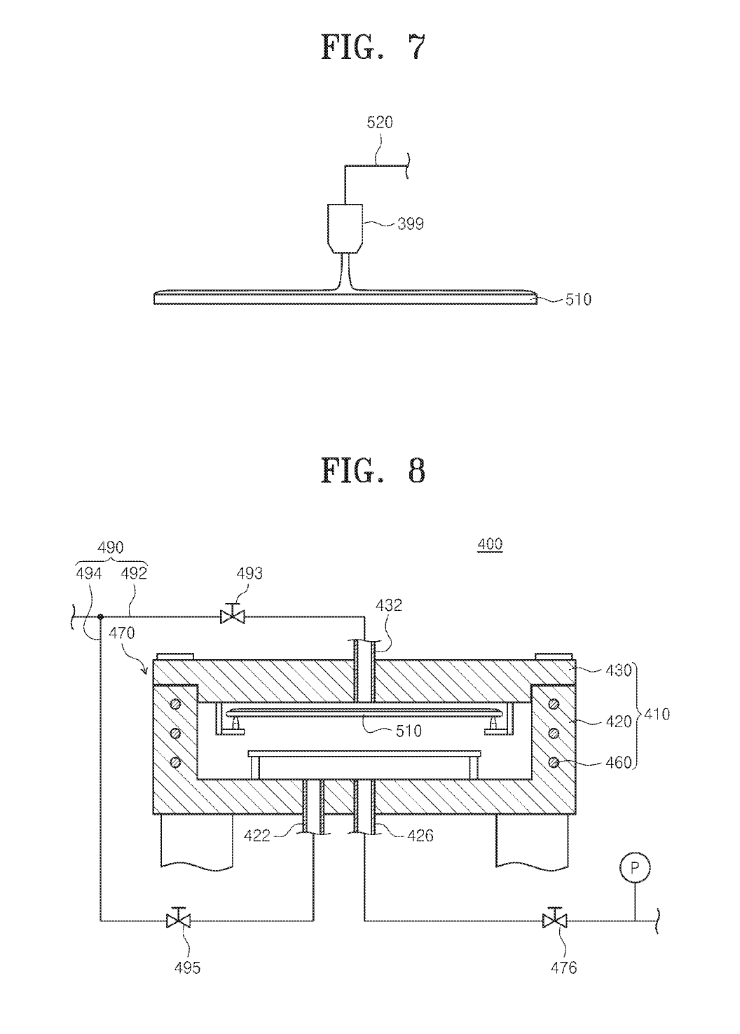

Hereinafter, a procedure of rinsing the treatment space 412 of the high-pressure chamber 410 will be more described in more detail. FIG. 6 is a flowchart illustrating the step of rinsing the inner part of the high-pressure chamber of FIG. 4, and FIGS. 7 and 8 are sectional views illustrating the procedure of rinsing the inner part of the high-pressure chamber of FIG. 6. Before describing the procedure of rinsing the inner part of the high-pressure chamber 410, the high-pressure chamber 410 has an inner space sealed from the outside and the substrate treatment process is performed by the critical pressure and the critical temperature. Accordingly, when the second process chamber 280 is modified to directly supply the organic solvent to the treatment space 412, the failure probability of the treatment of the substrate “W” may be increased. Hereinafter, description will be made regarding that the organic solvent is supplied to the treatment space 412 from the outside by way of example according to the first embodiment of the inventive concept. The cleaning process of the high-pressure chamber 410 is performed for aging the second process chamber 280 or for removing contaminant remaining in the treatment space 412, after the second process chamber 280 is set up. In addition, the cleaning process may be performed to remove the remaining contaminant from the treatment space 412 after the drying process is finished with respect to the substrate “W”.

Referring to FIGS. 6 to 8, when performing the cleaning process for the inner part of the high-pressure chamber 410, the dummy substrate 510 temporarily stored in the buffer unit 220 is carried to the first process chamber 260 by the main robot 244. When the dummy substrate 510 is seated on the spin head 340, the spray member 380 supplies the organic solvent onto the dummy substrate 510. The spray member 380 supplies the organic solvent onto the dummy substrate 510 such that the organic solvent on the dummy substrate 510 has a specific thickness or more. For example, the spray member 380 may supply the organic solvent at a preset flow rate.

When the organic solvent remains with a specific thickness or more on the dummy substrate 510, the main robot 244 carries the dummy substrate 510 to the second process chamber 280. The high-pressure chamber 410 is moved to the open position and the dummy substrate 510 is seated on the substrate support unit 440. When the dummy substrate 510 is seated, the high-pressure chamber 410 is moved to the closed position. When the supercritical atmosphere is formed in the treatment space 412, the treatment fluid is supplied into the treatment space 412. The treatment fluid is changed to the fluid in the supercritical state. The supercritical fluid removes a non-polar contaminant remaining in the treatment space 412 and the polar solvent removes a polar contaminant.

When the cleaning process is finished with respect to the high-pressure chamber 410, the supplying of the treatment fluid is stopped and the supercritical atmosphere is released. The high-pressure chamber 410 is moved to the open position and the main robot 244 carries the dummy substrate 510 to the buffer unit 220.

Alternatively, the main robot 244 carries the dummy substrate 510 to the first process chamber 260 to repeatedly perform the cleaning process for the inner part of the high-pressure chamber 410.

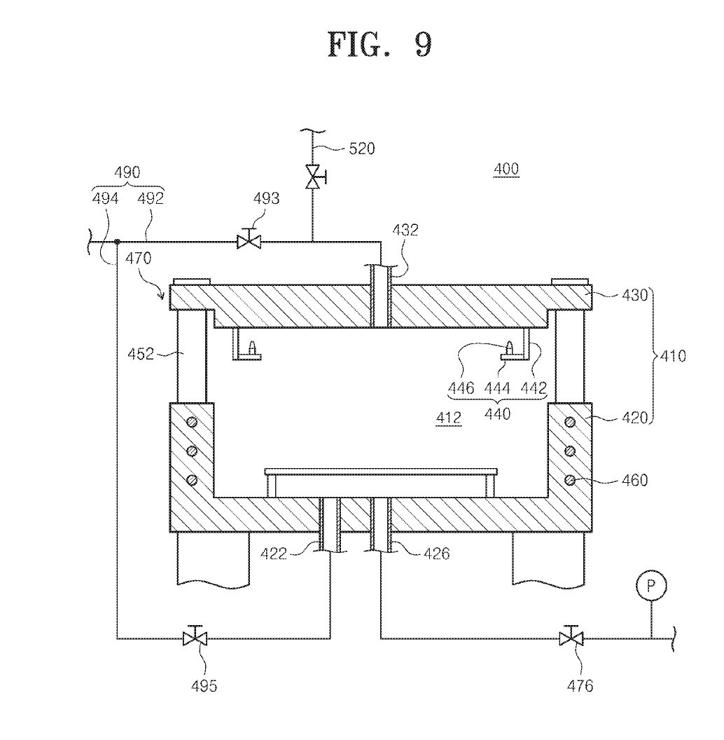

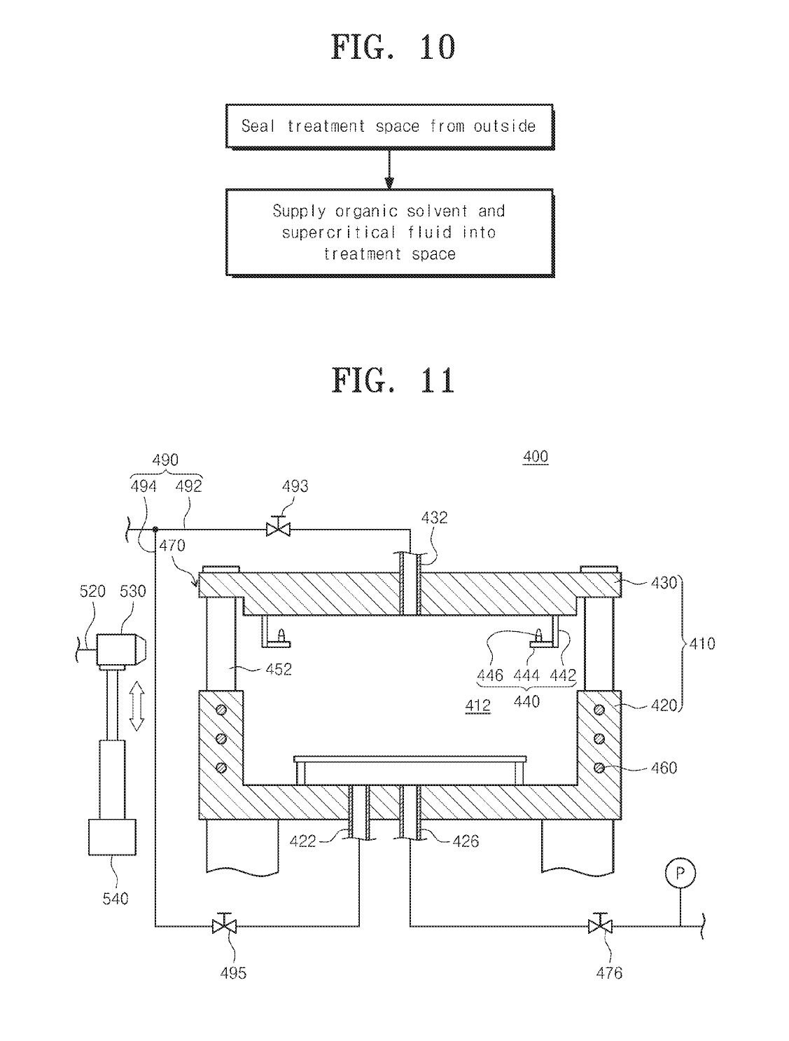

Hereinafter, the cleaning process for the inner part of the high-pressure chamber 410 will be described according to the second embodiment. Referring to FIGS. 9 and 10, a solvent supply line 520 may be linked to a fluid supply line 490. When performing the cleaning process for the inner part of the high-pressure chamber 410, the high-pressure chamber 410 is moved to the closed position and the treatment space 412 is switched to be under the supercritical atmosphere. The treatment fluid and the organic solvent are supplied to the treatment space 412 through the upper supply port 432. The treatment fluid and the organic solvent may be simultaneously supplied. Alternatively, the organic solvent may be supplied earlier than the treatment fluid. Accordingly, the second process chamber 280 may clean polar contaminants from the fluid supply line 490 as well as the treatment space 412.

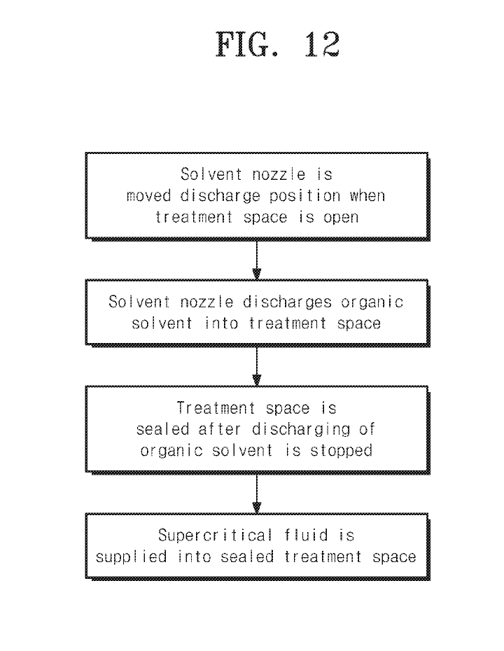

Hereinafter, the cleaning process for the inner part of the high-pressure chamber 410 will be described according to the third embodiment. Referring to FIGS. 11 and 12, the solvent supply unit 500 may further include a solvent nozzle 530 and a nozzle moving member 540. The solvent supply line 520 may be connected with the solvent nozzle 530. The solvent nozzle 530 may be positioned adjacent to the second process chamber 280. The solvent nozzle 530 may be positioned outside the treatment space 412. The solvent nozzle 530 may be positioned adjacent to the entrance for the substrate “W” in the high-pressure chamber 410. The solvent nozzle 530 may be moved to a discharge position and a standby position by the nozzle moving member 540. In this case, the discharge position is defined as a position that a discharge port of the solvent nozzle 530 faces the entrance of the substrate “W” in the high-pressure chamber 410 and the standby position is defined as a position out of the discharge position.

When performing the cleaning process for the inner part of the high-pressure chamber 410, the high-pressure chamber 410 is moved to the open position and the solvent nozzle 530 may be moved to the discharge position. The solvent nozzle 530 may supply the organic solvent to the treatment space 412. The solvent nozzle 530 may supply a preset amount of organic solvent. When the supply of the organic solvent is completed, the high-pressure chamber 410 is moved to the closed position and the treatment space 412 is switched to be under the supercritical atmosphere. Thereafter, the supercritical fluid is supplied to the treatment space 412 and the cleaning process is performed with respect to the high-pressure chamber 410.

Although the above description has been made regarding that the supercritical fluid is supplied to dry the substrate “W”, the present embodiment is not limited thereto but is applicable to the cleaning or etching process for the substrate “W”.

As described above, according to an embodiment of the inventive concept, the cleaning medium including the supercritical fluid having the non-polar property and the organic solvent having the polar property is supplied inside the supercritical treatment device. Accordingly, the cleaning efficiency of the chamber may be improved with respect to the non-polar contaminant and the polar contaminant.

In addition, according to an embodiment of the inventive concept, since the cleaning efficiency is improved with respect to the non-polar contaminant and the polar contaminant, the supercritical treatment device may be rapidly cleaned.

While the inventive concept has been described with reference to exemplary embodiments thereof, it will be apparent to those of ordinary skill in the art that various changes and modifications may be made thereto without departing from the spirit and scope of the inventive concept as set forth in the following claims.

What is claimed is:

1. A method for cleaning a chamber having a treatment space for treating a substrate, the method comprising:
cleaning the chamber by supplying a cleaning medium into the treatment space,
wherein the cleaning medium includes a supercritical fluid having a non-polar property and an organic solvent having a polar property.

2. The method of claim 1, wherein the organic solvent is supplied onto a dummy substrate from an outside of the chamber, and
wherein the dummy substrate having the organic solvent supplied at a specific thickness is provided in the treatment space.

3. The method of claim 2, wherein the supercritical fluid is supplied to the treatment space through a fluid supply line connected with the chamber, in a state that the dummy substrate is provided in the treatment space and the treatment space is sealed from the outside.

4. The method of claim 1, wherein the organic solvent is supplied into the treatment space from a solvent nozzle provided at an outside of the chamber, in a state that the treatment space is open to the outside.

5. The method of claim 4, wherein the treatment space is sealed from the outside after the organic solvent is supplied into the treatment space and then the supercritical fluid is supplied into the treatment space through a fluid supply line connected with the chamber.

6. The method of claim 1, wherein the organic solvent is supplied into the treatment state through a solvent supply line connected with the chamber in a state that the treatment space is sealed from an outside.

7. The method of claim 6, wherein the supercritical fluid is supplied into the treatment space through a fluid supply line connected with the chamber, in the state that the treatment space is sealed from the outside,
wherein the solvent supply line is connected with the fluid supply line, and
wherein the organic solvent is supplied to the treatment space through the fluid supply line.

8. The method of claim 7, wherein the organic solvent and the supercritical fluid are simultaneously supplied.

9. The method of claim 1, wherein the chamber is a high-pressure chamber to perform a supercritical treatment process with respect to the substrate.

10. The method of claim 9, wherein the supercritical fluid includes a carbon dioxide (CO₂).

11. The method of claim 10, wherein the organic solvent includes one of methanol, ethanol, 1-propanol, acetone, acetonitrile, chloroform, dichloromethane, and ethyl acetate.

12. A method for treating a substrate, the method comprising:
cleaning an inner part of a chamber having a treatment space therein; and
treating the substrate by supplying a supercritical fluid into the treatment space,
wherein the cleaning of the inner part of the chamber includes:
cleaning the chamber by supplying a cleaning medium to the treatment space, and
wherein the cleaning medium includes a supercritical fluid having a non-polar property and an organic solvent having a polar property.

13. The method of claim 12, wherein the treating of the substrate includes:
drying the substrate.

14. The method of claim 12, wherein the cleaning of the inner part of the chamber further includes:
supplying the organic solvent onto a dummy substrate from an outside of the chamber;
providing the dummy substrate having the organic solvent supplied at a specific thickness in the treatment space; and
supplying the supercritical fluid into the treatment space through a fluid supply line connected with the chamber, in a state that the treatment space is sealed from the outside when the dummy substrate is provided in the treatment space.

15. The method of claim 12, wherein the organic solvent is supplied into the treatment space from a solvent nozzle provided at an outside of the chamber, in a state that the treatment space is open to the outside, and
wherein the treatment space is sealed from the outside after the organic solvent is supplied into the treatment space and then the supercritical fluid is supplied into the treatment space through a fluid supply line connected with the chamber.

16. The method of claim 12, wherein the organic solvent is supplied into the treatment state through a solvent supply line connected with the chamber in a state that the treatment space is sealed from an outside,
wherein the supercritical fluid is supplied into the treatment space through a fluid supply line connected with the chamber, in the state that the treatment space is sealed from the outside,
wherein the solvent supply line is connected with the fluid supply line, and
wherein the organic solvent is supplied into the treatment space through the fluid supply line.

17. The method of claim 12, wherein the supercritical fluid includes CO₂, and
wherein the organic solvent includes one of methanol, ethanol, 1-propanol, acetone, acetonitrile, chloroform, dichloromethane, and ethyl acetate.

18. An apparatus for treating a substrate, the apparatus comprising:
a chamber having a treatment space therein;
a fluid supply line connected with the chamber and configured to supply a supercritical fluid having a non-polar property into the treatment space; and
a solvent supply unit configured to supply an organic solvent, which has a polar property, into the treatment space.

19. The apparatus of claim 18, wherein the chamber is a drying chamber configured to perform a process of drying the substrate,
wherein the apparatus further includes a liquid treatment chamber configured to perform a liquid treatment process with respect to the substrate,
wherein the solvent supply unit includes:
a dummy substrate; and
a solvent supply line connected with the liquid treatment chamber and configured to supply the organic solvent to the dummy substrate,
wherein the organic solvent is supplied onto the dummy substrate in the liquid treatment chamber, and
wherein the organic solvent is supplied into the treatment space as the dummy substrate having the organic solvent is provided into the treatment space.

20. The apparatus of claim 18, wherein the solvent supply unit includes:
a solvent supply provided independently from the chamber outside the chamber and configured to directly supply the organic solvent into the treatment space in a state that the treatment space is open.

21. The apparatus of claim 18, wherein the solvent supply unit includes:
a solvent supply line connected with the fluid supply unit and configured to supply the organic solvent.
